(19) United States
(12) Patent Application Publication
(10) Pub. No.: US 2024/0074043 A1
(43) Pub. Date: Feb. 29, 2024

(54) FLEXIBLE CIRCUIT BOARD AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Fei LI, Beijing (CN); Wenxiao NIU, Beijing (CN); Zhihui YAN, Beijing (CN); Huinan SHI, Beijing (CN); Xu LU, Beijing (CN)

(21) Appl. No.: 18/271,862

(22) PCT Filed: Feb. 26, 2021
(86) PCT No.: PCT/CN2021/078130

§ 371 Date: Jul. 12, 2023

(51) Int. Cl. H05K 1/02; G06F 3/041; H01L 23/00; H05K 1/11; H10K 59/131; H10K 59/40

(52) U.S. Cl. CPC H05K 1/028; G06F 3/0412; G06F 3/04164; H01L 24/32; H05K 1/118; H10K 59/131; H10K 59/40; H01L 2224/32227; H05K 2201/10128

(57) ABSTRACT

Embodiments in the present disclosure provide a flexible circuit board and a display device. The flexible circuit board includes a base material, a plurality of binding pins, and a protective layer. The plurality of binding pins are located on the base material, extend in a first direction, and are arranged in a second direction; the protective layer is located on the side of the binding pins facing away from the base material, and includes a plurality of first openings and second openings for exposing the plurality of binding pins, the size of the first openings being greater than that of the second openings; and one binding pin corresponds to one first opening and at least one second opening, and the second opening is located on at least one side of the first opening in the first direction.

### CROSS REFERENCE TO RELATED APPLICATIONS

The present disclosure is a US National Stage of International Application No. PCT/CN2021/078130, filed on Feb. 26, 2021, the entire contents of which are incorporated herein by reference.

### TECHNICAL FIELD

The present disclosure relates to the field of display technology, in particular to a flexible circuit board and a display device.

### BACKGROUND

With the development of display technology, the display technology is more and more widely used, and users have higher and higher requirements on the experience of using display products. In the era of pursuing visual effects, the full-screen display and large-screen display effect of display products such as mobile phones and computers are increasingly favored by users.

A full-screen display, with its large screen-to-body ratio and ultra-narrow bezel, can greatly improve the visual effect of viewers compared with an ordinary display screen, thus attracting extensive attention. In order to increase the screen-to-body ratio of the screen, a flexible printed circuit (FPC) is usually bound to the edge of the display screen, and then a control device is bound to the flexible circuit board and bent at the back side of a display surface to save the edge area of the screen for setting more display areas.

Generally, in order to ensure the effective contact area of binding of the flexible circuit board, a gold finger is often set long, and part of the gold finger is exposed to the air and corrosion phenomenon occurs after the binding is completed, thereby affecting the binding reliability.

### SUMMARY

Embodiments of the present disclosure provide a flexible circuit board, including: a base material; a plurality of bonding pins, located on the base material, extending in a first direction and arranged in a second direction; wherein the first direction and the second direction intersect; and a protective layer, located on a side of the bonding pins facing away from the base material; wherein the protective layer includes a plurality of first openings and a plurality of second openings for exposing the plurality of bonding pins, wherein a size of the first opening is greater than a size of the second opening; one bonding pin corresponds to one first opening and at least one second opening, and the second opening is located on at least one side of the first opening in the first direction.

Optionally, in the embodiments of the present disclosure, one bonding pin corresponds to one first opening and a plurality of second openings, and the plurality of second openings are distributed on two sides of the first opening in the first direction in an array manner.

Optionally, in the embodiments of the present disclosure, a width of the first opening in the second direction is smaller than or equal to a width of the bonding pin in the second direction; a width of the first opening in the first direction is smaller than or equal to half a width of the bonding pin in the first direction.

Optionally, in the embodiments of the present disclosure, the width of the bonding pin in the first direction is 0.8 mm-1.5 mm; the width of the bonding pin in the second direction is 0.1 mm-0.2 mm; a distance between two adjacent bonding pins in the second direction is 0.05 mm-0.1 mm; the width of the first opening in the first direction is 0.3 mm-0.75 mm; the width of the first opening in the second direction is 0.06 mm-0.2 mm; a width of the second opening in the first direction is 0.03 mm-0.05 mm; a width of the second opening in the second direction is 0.03 mm-0.05 mm; a distance between two adjacent second openings is 0.01 mm-0.03 mm.

Optionally, in the embodiments of the present disclosure, the flexible circuit board further includes: a conductive layer, located on the bonding pins within the first opening and the second opening; wherein a surface of a side of the conductive layer facing away from the bonding pins is flush with a surface of a side of the protective layer facing away from the bonding pins.

Optionally, in the embodiments of the present disclosure, a material of the conductive layer comprises nickel and/or gold.

Optionally, in the embodiments of the present disclosure, the plurality of bonding pins include a plurality of first bonding pins and a plurality of second bonding pins; wherein the first bonding pin and the second bonding pin are located at two ends of the flexible circuit board respectively, and the first bonding pin and the second bonding pin are located at the same side of the base material.

Optionally, in the embodiments of the present disclosure, the plurality of bonding pins include a plurality of first bonding pins and a plurality of second bonding pins; the protective layer includes a first protective layer and a second protective layer; the first bonding pin and the second bonding pin are located at two ends of the flexible circuit board respectively; the first bonding pin is located at one side of the base material, and the second bonding pin is located at a side of the base material facing away from the first bonding pin; the first protective layer is located on a side of the first bonding pin facing away from the base material, and the second protective layer is located on a side of the second bonding pin facing away from the base material.

Correspondingly, the embodiments of the present disclosure further provide a display device, including: a display panel and any one of the flexible circuit boards described above; wherein, the display panel includes a display area and a non-display area surrounding the display area; connecting pins are provided in the non-display area at one side of the display area; one of the bonding pins on the flexible circuit board corresponds to one of the connecting pins on the display panel; the bonding pins and the connecting pins corresponding to each other are bound by an anisotropic conductive adhesive film.

Optionally, in the embodiments of the present disclosure, the display panel includes: a base substrate; a driving circuit layer, located on the base substrate and including a plurality of display signal leads; an organic light-emitting diode device layer, located at a side of the driving circuit layer facing away from the base substrate; a packaging layer, located at a side of the organic light-emitting diode device layer facing away from the base substrate; and a touch functional layer, located at a side of the packaging layer facing away from the organic light-emitting diode device layer and including a plurality of touch signal leads; wherein the connecting pins include display connecting pins and touch connecting pins; one of the display signal leads is correspondingly connected with one of the display connecting pins, and one of the touch signal leads is correspondingly connected with one of the touch connecting pins; the display device includes two flexible circuit boards, which are a display flexible circuit board and a touch flexible circuit board, respectively, wherein the touch flexible circuit board is configured to be bound to the touch connecting pins, and the display flexible circuit board is configured to be bound to the display connecting pins.

Optionally, in the embodiments of the present disclosure, the plurality of bonding pins in the touch flexible circuit board include a plurality of first touch bonding pins and a plurality of second touch bonding pins; the first touch bonding pin and the second touch bonding pin are located at two ends of the touch flexible circuit board, and the first touch bonding pin and the second touch bonding pin are located at the same side of the base material in the touch flexible circuit board; the first touch bonding pin and the touch connecting pin are mutually bound; the plurality of bonding pins in the display flexible circuit board include a plurality of first display bonding pins and a plurality of second display bonding pins, wherein the first display bonding pin and the second display bonding pin are located at two ends of the display flexible circuit board, and the first display bonding pins and the second display bonding pins are located at two sides of the base material in the display flexible circuit board; the second display bonding pin and the display connecting pin are mutually bound; the second touch bonding pin and the second display bonding pin are mutually bound.

### BRIEF DESCRIPTION OF FIGURES

FIG. 1 is a structural schematic top view of a flexible circuit board provided by embodiments of the present disclosure.

FIG. 2 is a schematic cross-sectional view at a dashed line CC′ in FIG. 1.

FIG. 3 is another structural schematic top view of a flexible circuit board provided by embodiments of the present disclosure.

FIG. 4 is another structural schematic top view of a flexible circuit board provided by embodiments of the present disclosure.

FIG. 5 is a structural schematic top view of a display device provided by embodiments of the present disclosure.

FIG. 6 is a structural schematic diagram of film layers of a display panel in a display area in embodiments of the present disclosure.

FIG. 7 is a schematic cross-sectional view in a second direction F2 within a dashed box 01 in FIG. 5.

FIG. 8 is a schematic cross-sectional view in the second direction F2 within a dashed box Q2 in FIG. 5.

FIG. 9 is a schematic cross-sectional view in the second direction F2 within a dashed box Q3 in FIG. 5.

### DETAILED DESCRIPTION

Aiming at the problem that gold fingers of a flexible circuit board are easy to corrode, thereby affecting binding reliability, embodiments of the present disclosure provide a flexible circuit board and a display device.

Specific embodiments of the flexible circuit board and the display device provided by the embodiments of the present disclosure will be described in detail below in conjunction with the accompanying drawings. The sizes and shapes of parts in the drawings do not reflect true scale and are merely intended to schematically describe the present disclosure.

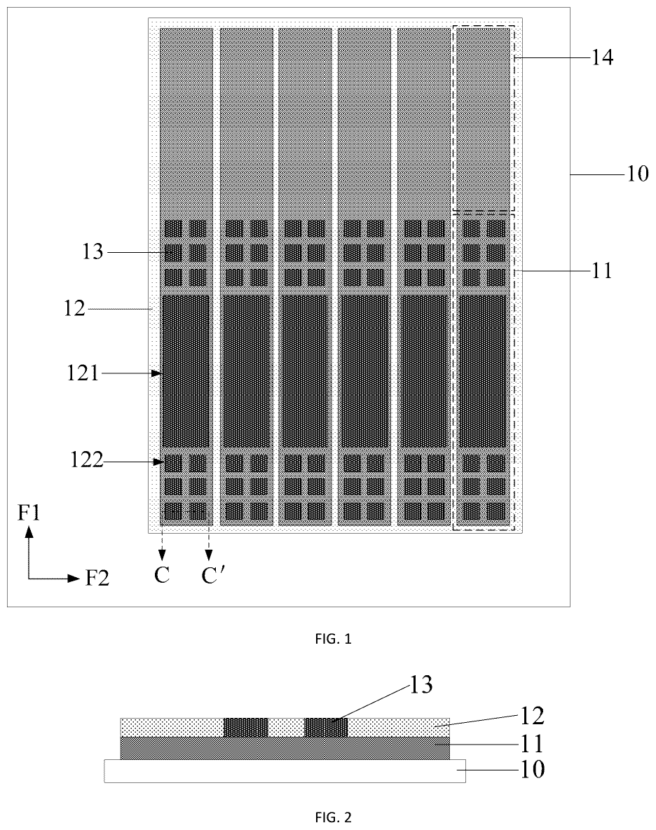

FIG. 1 is a structural schematic top view of a flexible circuit board provided by embodiments of the present disclosure. FIG. 2 is a schematic cross-sectional view at a dashed line CC′ in FIG. 1. As shown in FIGS. 1 and 2, the flexible circuit board provided by the embodiments of the present disclosure may include: a base material 10; a plurality of bonding pins 11, located on the base material 10, extending in a first direction F1 and arranged in a second direction F2; wherein the first direction F1 and the second direction F2 intersect, for example, the first direction F1 and the second direction F2 may be perpendicular to each other, and of course, an included angle between the first direction F1 and the second direction F2 may also be other values, which is not limited here; and a protective layer 12, located on a side of the bonding pins 11 facing away from the base material 10.

The protective layer 12 includes a plurality of first openings 121 and second openings 122 for exposing the bonding pins 11. A size of the first openings 121 is greater than a size of the second openings 122. One bonding pin 11 corresponds to one first opening 121 and at least one second opening 122, and the second opening 122 is located on at least one side of the first opening 121 in the first direction F1.

According to the flexible circuit board provided by the embodiments of the present disclosure, the protective layer is provided on the side of the bonding pins facing away from the base material, and includes the first openings and second openings for exposing the bonding pins, the size of the first opening is greater than the size of the second opening, and the bonding pin corresponds to one first opening and at least one second opening. In this way, the exposed area of the bonding pins can be reduced on the basis of ensuring the contact area of the bonding pins, and thus, the risk of the bonding pins being corroded can be reduced, and the binding reliability can be improved.

In the embodiments of the present disclosure, the flexible circuit board may be in binding connection with a display panel or other devices, a plurality of connecting pins are provided in the display panel or other devices, and the plurality of bonding pins in the flexible circuit board are respectively in binding connection with the plurality of connecting pins in the display panel or other devices. During specific implementation, the number, arrangement, shape and size of the bonding pins in the flexible circuit board may be set according to the number, arrangement, shape and size of the connecting pins in the display panel or other devices.

In addition, as shown in FIG. 1, the flexible circuit board may further include a plurality of signal lines 14 correspondingly connected to the bonding pins 11. Since the bonding pins in the flexible circuit board are in binding connection with the connecting pins in the display panel or other devices, the signal lines 14 in the flexible circuit board can transmit signals to the display panel or other devices. During specific implementation, the signal lines 14 in the flexible circuit board may be located on the same film layer as the bonding pins 11, so that the signal lines 14 and the bonding pins 11 can be fabricated by the same patterning process, thus reducing the process cost, in addition, the bonding pins 11 may be provided at the ends of the signal lines 14 so as to ensure good performance of connection between the bonding pins 11 and the corresponding signal lines 14.

Continuing to refer to FIG. 1, one bonding pin 11 corresponds to one first opening 121 and at least one second opening 122, since the size of the first opening 121 is greater than the size of the second opening 122, the area of the bonding pin 11 exposed by the first opening 121 is larger, and sufficient contact area between the bonding pin 11 and the corresponding connecting pin can be ensured when the bonding pin 11 is in binding connection with the corresponding connecting pin. Moreover, the second opening 122 is located on at least one side of the first opening 121 in the first direction F1, on the one hand, the length of the exposed bonding pin 11 in the first direction F1 can be increased, even if there is an error in the bonding process between the bonding pin 11 and the corresponding connecting pin, good bonding between the bonding pin 11 and the corresponding connecting pin can be ensured, on the other hand, due to the smaller size of the second opening 122, the exposed area of the bonding pin 11 can be reduced, thereby reducing the risk of the bonding pin 11 being corroded.

Optionally, the protective layer 12 may be made of a polyimide (PI) material, or made of other materials, which is not limited herein.

During specific implementation, in the flexible circuit board provided by the embodiments of the present disclosure, as shown in FIGS. 1 and 2, one bonding pin 11 corresponds to one first opening 121 and a plurality of second openings 122, and the plurality of second openings 122 are distributed on two sides of the first opening 121 in the first direction F1 in an array manner. By providing the second openings 122 on two sides of the first opening 121 in the first direction F1, the length of the exposed bonding pin 11 in the first direction F1 can be increased, so that there is sufficient contact area between the bonding pin 11 and the corresponding connecting pin, and even if there is an error in the bonding process between the bonding pin 11 and the corresponding connecting pin, good bonding between the bonding pin 11 and the corresponding connecting pin can be ensured. Moreover, the exposed area at two ends of the bonding pin 11 can be reduced, thus reducing the risk of the bonding pin 11 being corroded. In the actual process, the bonding pin 11 is in binding connection with the corresponding connecting pin through an anisotropic conductive adhesive film, and the plurality of second openings 122 are arranged in an array distribution, so that the distribution of the anisotropic conductive adhesive film can be more uniform, and the reliability of binding between the bonding pin 11 and the corresponding connecting pin is higher.

It should be noted that in FIG. 1, illustration is made by taking two sides of the first opening 121 in the first direction F1 being each provided with six second openings 122 as an example, and during specific implementation, the number and distribution of the second openings 122 may be set according to the actual size of the space, which is not limited here. Moreover, in FIG. 1, illustration is made by taking the first opening 121 being in a rectangular shape and the second opening 122 being in a square shape as an example, and during specific implementation, the first opening 121 and the second opening 122 may also be in other shapes, which is not limited herein.

Optionally, in the flexible circuit board provided by the embodiments of the present disclosure, as shown in FIG. 1, the width of the first opening 121 in the second direction F2 is smaller than or equal to the width of the bonding pin 11 in the second direction F2, so that the protective layer 12 can cover a gap between two adjacent bonding pins 11 in the second direction F2 to avoid short circuit between two adjacent bonding pins 11. Moreover, the width of the first opening 121 in the first direction F1 is smaller than or equal to half the width of the bonding pin 11 in the first direction F1, so that enough space can be reserved, and the second opening 122 is provided on at least one side of the first opening 121 in the first direction F1 to reduce the exposed area of the bonding pin 11, so that the risk of the bonding pin 11 being corroded is lower.

In practical application, in the flexible circuit board provided by the embodiments of the present disclosure, as shown in FIG. 1, the width of the second opening 122 in the first direction F1 is smaller than the width of the first opening 121 in the first direction F1; the width of the second opening 122 in the second direction F2 is smaller than the width of the first opening 121 in the second direction, so that the size of the second opening 122 is smaller than the size of the first opening 121, and the area of the bonding pin 11 exposed by the second opening 122 is smaller, thereby reducing the risk of the bonding pin 11 being corroded.

Optionally, in the flexible circuit board provided by the embodiments of the present disclosure, as shown in FIG. 1, the width of the bonding pin 11 in the first direction F1 is 0.8 mm-1.5 mm; the width of the bonding pin 11 in the second direction F2 is 0.1 mm-0.2 mm; the distance between two adjacent bonding pins 11 in the second direction F2 is 0.05 mm-0.1 mm. For example, the width of the bonding pin 11 in the first direction F1 may be 0.91 mm, the width of the bonding pin 11 in the second direction F2 may be 0.155 mm, and the distance between two adjacent bonding pins 11 in the second direction F2 may be 0.09 mm. Of course, the size of the bonding pin 11 and the distance between the bonding pins 11 may be other values and may be set according to the space of the flexible circuit board, which is not limited herein.

Optionally, in the flexible circuit board provided by the embodiments of the present disclosure, referring to FIG. 1, the width of the first opening 121 in the first direction F1 is 0.3 mm-0.75 mm; the width of the first opening 121 in the second direction F2 may be 0.06 mm to 0.2 mm. For example, the width of the first opening 121 in the first direction F1 may be 0.395 mm, and the width of the first opening 121 in the second direction F2 may be 0.115 mm. Of course, the size of the first opening 121 may be other values and may be set according to the size of the bonding pin 11, which is not limited herein.

Optionally, in the flexible circuit board provided by the embodiments of the present disclosure, as shown in FIG. 1, the width of the second opening 122 in the first direction F1 is 0.03 mm-0.05 mm; the width of the second opening 122 in the second direction F2 is 0.03 mm-0.05 mm; the distance between two adjacent second openings 122 may be 0.01 mm to 0.03 mm. For example, the second opening 122 may be a 0.045 mm×0.045 mm square opening, and the distance between two adjacent second openings 122 may be 0.025 mm. Of course, the second opening 122 may also be in other shapes, and the size of the second opening 122 and the distance between the second openings 122 may also be other values, and may be set according to the size of the bonding pin 11 and the first opening 121, which is not limited herein.

Further, the flexible circuit board provided by the embodiments of the present disclosure, as in FIGS. 1 and 2, may further include: a conductive layer 13, located on the bonding pins 11 within the first openings 121 and the second openings 122; wherein the surface of the side of the conductive layer 13 facing away from the bonding pins 11 is flush with the surface of the side of the protective layer 12 facing away from the bonding pins 11.

In the embodiments of the present disclosure, the conductive layer 13 is adopted to fill the first openings 121 and the second openings 122 in the protective layer 12, and the surface of the side of the conductive layer 13 facing away from the bonding pins 11 is flush with the surface of the side of the protective layer 12 facing away from the bonding pins 11, so that the bonding flatness can be ensured, thereby further improving the reliability of binding between the bonding pins 11 and the corresponding connecting pins. Optionally, the sum of the thickness of the conductive layer 13 and the thickness of the bonding pin 11 is about 20 μm.

During specific implementation, the bonding pin 11 may be made of metallic copper, which is good in conductivity and low in cost, but the metallic copper is easy to oxidize, so that the conductive layer 13 is provided to protect the bonding pins 11 to prevent the bonding pins 11 from being corroded. The conductive layer 13 may be made of a metallic material which is not easy to oxidize. Optionally, the conductive layer 13 may be made of nickel and/or gold. Of course, the bonding pin 11 and the conductive layer 13 may also be made of other materials, which is not limited herein.

In practical application, the flexible circuit board provided by the embodiments of the present disclosure is implemented by at least the following two approaches, which will be described in detail below in conjunction with the accompanying drawings.

Approach One

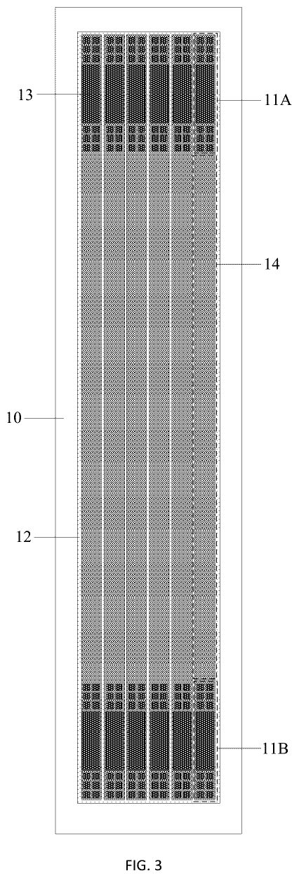

FIG. 3 is another structural schematic top view of a flexible circuit board provided by embodiments of the present disclosure. As shown in FIG. 3, the plurality of bonding pins in the flexible circuit board include a plurality of first bonding pins 11A and a plurality of second bonding pins 11B; the first bonding pins 11A and the second bonding pins 11B are respectively located at two ends of the flexible circuit board, and the first bonding pins 11A and the second bonding pins 11B are located at the same side of the base material 10.

In this way, the flexible circuit board in Approach One can be in binding connection with two devices located on the same side of the base material 10. In addition, the flexible circuit board in Approach One may further include a protective layer 12 and a conductive layer 13.

Approach Two

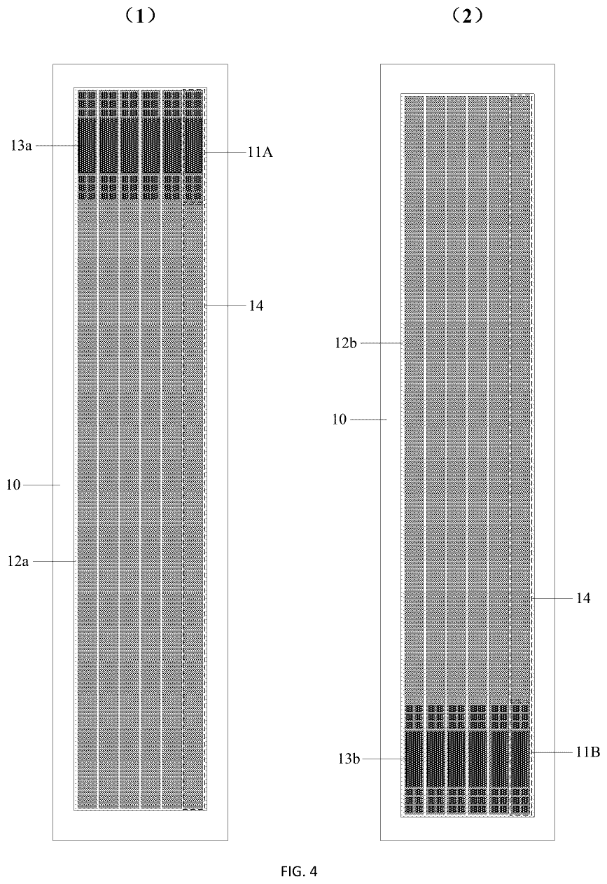

FIG. 4 is another structural schematic top view of a flexible circuit board provided by embodiments of the present disclosure, wherein (1) in FIG. 4 is a schematic view of one side of the flexible circuit board, and (2) in FIG. 4 is a schematic view of the other side of the flexible circuit board. As shown in FIG. 4, the plurality of bonding pins in the flexible circuit board include a plurality of first bonding pins 11A and a plurality of second bonding pins 11B; the protective layer includes a first protective layer 12a and a second protective layer 12b; the first bonding pins 11A and the second bonding pins 11B are respectively located at two ends of the flexible circuit board; as shown in (1) in FIG. 4, the first bonding pins 11A are located on one side of the base material 10, the first protective layer 12a is located on the side of the first bonding pins 11a facing away from the base material 10; as (2) shown in in FIG. 4, the second bonding pins 11B are located on the side of the base material 10 facing away from the first bonding pins 11A, and the second protective layer 12b is located on the side of the second bonding pins 11B facing away from the base material 10.

In this way, the flexible circuit board in Approach Two can be in binding connection with two devices located on two sides of the base material 10. In addition, the conductive layer in the flexible circuit board includes a first conductive layer and a second conductive layer, as shown in (1) in FIG. 4, the first conductive layer 13a is located on the side of the first bonding pins 11A facing away from the base material 10, as shown in (2) in FIG. 4, the second conductive layer 13b is located on the side of the second bonding pins 11B facing away from the base material 10.

In addition, besides the above-mentioned Approach One and Approach Two, the structure of the flexible circuit board may be set according to actual needs, for example, a plurality of bonding pins may be provided only at one end of the flexible circuit board.

Based on the same inventive concept, the embodiments of the present disclosure further provide a display device, which can be applied to any product or component having a display function such as a mobile phone, a tablet computer, a television set, a display, a notebook computer, a digital photo frame and a navigator. Since the problem solving principle of the display device is similar to that of the flexible circuit board described above, the implementation of the display device can refer to the implementation of the flexible circuit board described above, and the description will not be repeated here.

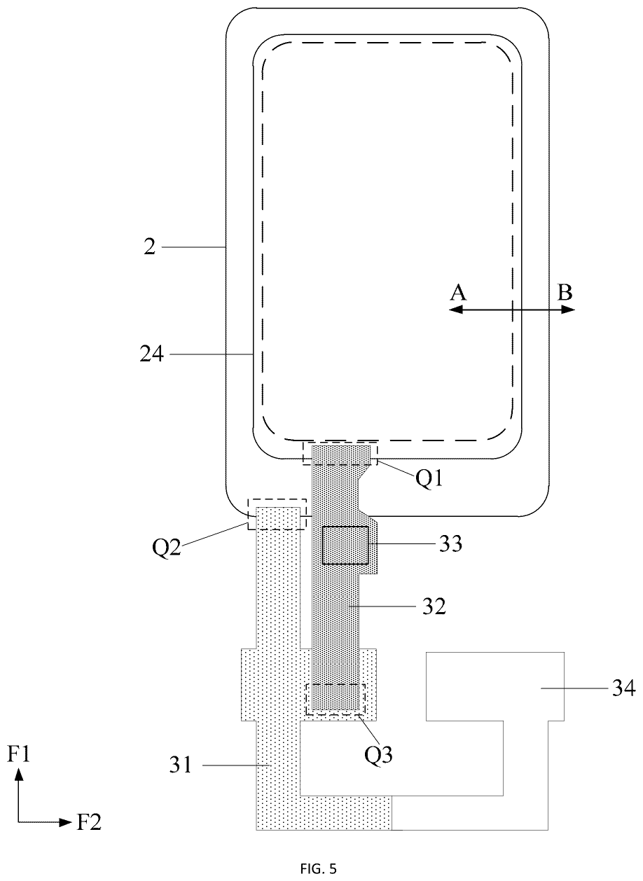

FIG. 5 is a structural schematic top view of a display device provided by the embodiments of the present disclosure, as shown in FIG. 5, the display device provided by the embodiments of the present disclosure may include a display panel 2 and any one of the above flexible circuit boards (e.g., 31 or 32 in FIG. 5).

The display panel 2 includes a display area A and a non-display area B surrounding the display area A; connecting pins (not shown in FIG. 5) are provided within the non-display area B located on one side of the display area A; one bonding pin on the flexible circuit board corresponds to one connecting pin on the display panel; and the bonding pins and the connecting pins corresponding to each other are bound by anisotropic conductive adhesive film.

According to the display device provided by the embodiments of the present disclosure, the connecting pins in the display panel are in binding connection with the bonding pins in the flexible circuit board, and since the protective layer is provided in the flexible circuit board, the protective layer includes the first and second openings for exposing the bonding pins, the size of the first openings is greater than that of the second openings, and the bonding pin corresponds to one first opening and at least one second opening, when the bonding pins are in binding connection with the corresponding connecting pins, there is sufficient contact area between the bonding pins and the corresponding connecting pins, and the exposed area of the bonding pins is smaller, therefore the risk of the bonding pins being corroded is lower, and the binding reliability is higher.

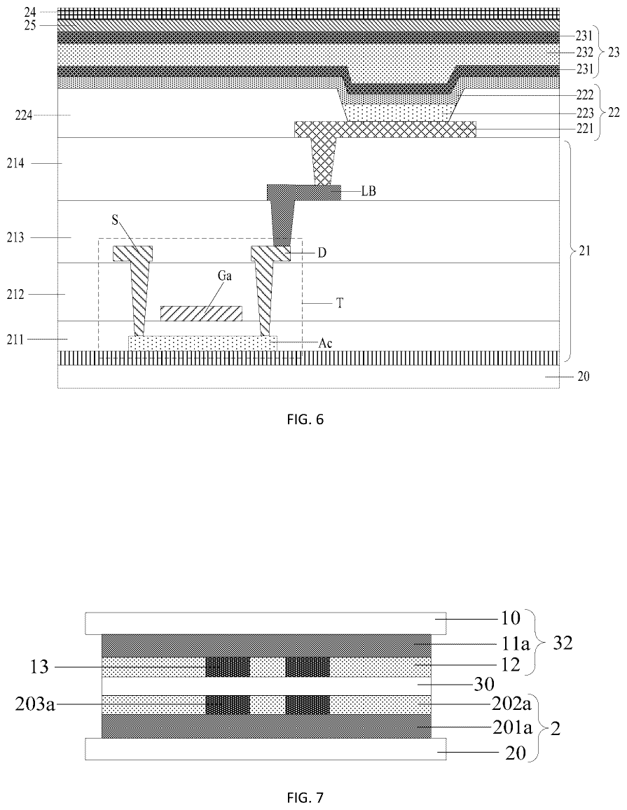

FIG. 6 is a structural schematic diagram of film layers of a display panel in a display area in embodiments of the present disclosure, as shown in FIG. 6, the display panel may include: a base substrate 20; a driving circuit layer 21, located on the base substrate 20; wherein the driving circuit layer 21 includes a plurality of display signal leads (not shown in FIG. 6); the driving circuit layer 21 may include components such as a thin film transistor T and a capacitor structure, and the thin film transistor T may include an active layer Ac, a source S, a drain D and a gate Ga; the display signal leads in the driving circuit layer 21 may be electrically connected with the thin film transistor T; an organic light-emitting diode device layer 22, located on the side of the driving circuit layer 21 facing away from the base substrate 20; wherein, the organic light-emitting diode device layer 22 may include a first electrode 221, a second electrode 222, an organic light-emitting layer 223 and a pixel defining layer 224; the first electrode 221 may be connected with the drain D of the thin film transistor T through a conductive connection portion LB, and the pixel defining layer 224 is used to define an area of each pixel in the display panel; a packaging layer 23, located on the side of the organic light-emitting diode device layer 22 facing away from the base substrate 10; wherein, the packaging layer 23 may include inorganic film layers 231 and an organic film layer 232 that are stacked, and the organic film layer 232 may be located between two adjacent inorganic film layers 231; and a touch functional layer 24, located on the side of the packaging layer 23 facing away from the organic light-emitting diode device layer 22; wherein the touch functional layer 24 includes a plurality of touch signal leads (not shown in FIG. 6); a touch blocking layer 25 is provided between the touch functional layer 24 and the packaging layer 23, and can prevent metal atoms in the touch functional layer 24 from entering the packaging layer 23.

In addition, the display panel may further include a gate insulating layer 211 located between the active layer Ac and the gate Ga, an interlayer insulating layer 212 located between the gate Ga and the source S, a first planarization layer 213 located between the source S and the conductive connection portion LB, and a second planarization layer 214 located between the conductive connection portion LB and the first electrode 221.

The connecting pins include display connecting pins and touch connecting pins; one display signal lead is correspondingly connected to one display connecting pin, and one touch signal lead is correspondingly connected to one touch connecting pin.

As shown in FIG. 5, the display device may include two flexible circuit boards, which are a display flexible circuit board 31 and a touch flexible circuit board 32, respectively, the touch flexible circuit board 32 is bound to the touch connecting pins, the display flexible circuit board 31 is bound to the display connecting pins, for example, the touch connecting pins may be located inside a dashed box Q1, the touch flexible circuit board 32 is in binding connection with the touch connecting pins at the dashed box Q1, the display connecting pins may be located inside a dashed box Q2, the display flexible circuit board 31 is in binding connection with the display connecting pins at the dashed box Q2, and in addition, the touch flexible circuit board 32 may also be in binding connection with the display flexible circuit board 31 at a dashed box Q3.

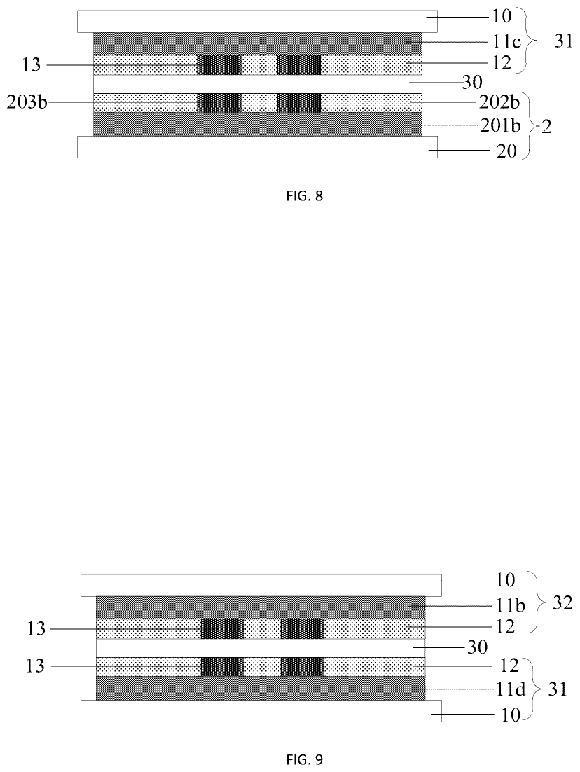

FIG. 7 is a schematic cross-sectional view in a second direction F2 within the dashed box 01 in FIG. 5, FIG. 8 is a schematic cross-sectional view in the second direction F2 within the dashed box Q2 in FIG. 5, and FIG. 9 is a schematic cross-sectional view in the second direction F2 within the dashed box Q3 in FIG. 5. Referring to FIGS. 5, 7 and 9, in the embodiments of the present disclosure, the plurality of bonding pins in the touch flexible circuit board 32 include a plurality of first touch bonding pins 11a and a plurality of second touch bonding pins 11b; the first touch bonding pin 11a and the second touch bonding pin 11b are located at two ends of the touch flexible circuit board, the first touch bonding pin 11a and the second touch bonding pin 11b are located at the same side of the base material 10 in the touch flexible circuit board, that is, the touch flexible circuit board 32 has the structure in Approach One described above. Within the dashed box Q1, the first touch bonding pin 11a and the touch connecting pin 201a are mutually bound.

Referring to FIGS. 5, 8 and 9, it is shown that the plurality of bonding pins in the flexible circuit board 31 include a plurality of first display bonding pins 11c and a plurality of second display bonding pins 11d; the first display bonding pin 11c and the second display bonding pin 11d are located at two ends of the display flexible circuit board 31, the first display bonding pin 11c and the second display bonding pin 11d are located at two sides of the base material 10 in the display flexible circuit board 31, that is, the display flexible circuit board 31 has the structure in Approach Two described above; the first display bonding pin 11c and the display connecting pin 201b are mutually bound, and the second touch bonding pin 11b and the second display bonding pin 11d are mutually bound.

Referring to FIGS. 5 and 7, within the dashed box Q1, the touch flexible circuit board 32 is in binding connection with the touch connecting pin 201a in the display panel 2 through an anisotropic conductive adhesive film 30, since a protective layer 12 is provided in the touch flexible circuit board 32, when the first touch bonding pin 11a and the touch connecting pin 201a are bound, there is sufficient contact area between the first touch bonding pin 11a and the touch connecting pin 201a, and the exposed area of the first touch bonding pin 11a is smaller, thus the risk of the first touch bonding pin 11a being corroded is lower. Furthermore, the display panel 2 may further include a third protective layer 202a and a third conductive layer 203a that are located on the side of the touch connecting pin 201a facing away from the base substrate 20, wherein, similar to the structure of the protective layer 12 in the touch flexible circuit board 32, the third protective layer 202a may also include first openings and second openings, the touch connecting pin 201a corresponds to one first opening and at least one second opening, and the third conductive layer 203a is located within the first opening and the second opening, and the surface of the third conductive layer 203a is flush with the surface of the third protective layer 202a. In this way, the risk of the touch connecting pin 201a being corroded is also reduced, and the binding reliability is further improved.

Referring to FIGS. 5 and 8, within the dashed box Q2, the display flexible circuit board 31 is in binding connection with the display connecting pin 201b in the display panel 2 through the anisotropic conductive adhesive film 30, since a protective layer 12 is provided in the display flexible circuit board 31, when the first display bonding pin 11c is in binding connection with the display connecting pin 201b, there is sufficient contact area between the first display bonding pin 11c and the display connecting pin 201b, and the exposed area of the first display bonding pin 11c is smaller, thus the risk of the first display bonding pin 11c being corroded is lower. Furthermore, the display panel 2 may further include a fourth protective layer 202b and a fourth conductive layer 203b that are located on the side of the display connecting pin 201b facing away from the base substrate 20, wherein, similar to the protective layer 12 in the display flexible circuit board 31, the fourth protective layer 202b may also include first openings and second openings, the display connecting pin 201b corresponds to one first opening and at least one second opening, and the fourth conductive layer 203b is located within the first opening and the second opening, and the surface of the fourth conductive layer 203b is flush with the surface of the fourth protective layer 202b. In this way, the risk of the display connecting pin 201b being corroded is also reduced, and the binding reliability is further improved.

Referring to FIGS. 5 and 9, within the dashed box Q3, the display flexible circuit board 31 is in binding connection with the touch flexible circuit board 32 through the anisotropic conductive adhesive film 30, since the display flexible circuit board 31 and the touch flexible circuit board 32 are each internally provided with the protective layer 12, when the second touch bonding pin 11b is in binding connection with the second display bonding pin 11d, there is sufficient contact area between the second touch bonding pin 11b and the second display bonding pin 11d, and the exposed areas of the second touch bonding pin 11b and the second display bonding pin 11d are both smaller, thus the risk of the second touch bonding pin 11b and the second display bonding pin 11d being corroded is lower.

In addition, as shown in FIG. 5, in the embodiments of the present disclosure, the above display device may further include a control device 33, a connector 34 and a main board (not shown in the figure), wherein the control device 33 may be a chip or the like, the touch flexible circuit board 32 is electrically connected to the control device 33, and the display flexible circuit board 31 is electrically connected to the main board through the connector 34.

According to the flexible circuit board and the display device provided by the embodiments of the present disclosure, the protective layer is provided in the flexible circuit board on the side of the bonding pins facing away from the base material, the protective layer includes the first and second openings for exposing the bonding pins, the size of the first openings is greater than that of the second openings, and the bonding pin corresponds to one first opening and at least one second opening. In this way, the exposed area of the bonding pins can be reduced on the basis of ensuring the contact area of the bonding pins, and thus, the risk of the bonding pins being corroded can be reduced, and the binding reliability can be improved.

Although preferred embodiments of the present disclosure have been described, those skilled in the art can make additional changes and modifications to these embodiments once they know the basic inventive concepts. Therefore, the appended claims are intended to be interpreted as including the preferred embodiments and all changes and modifications that fall within the scope of the present disclosure.

Obviously, those skilled in the art can make various modifications and variations to the embodiments of the present disclosure without departing from the spirit and scope of the embodiments of the present disclosure. Thus, if these modifications and variations made to the embodiments of the present disclosure are within the scope of the claims of the present disclosure and their equivalents, the present disclosure is also intended to include these modifications and variations.

1. A flexible circuit board, comprising:
a base material;
a plurality of bonding pins, located on the base material, extending in a first direction and arranged in a second direction; wherein the first direction and the second direction intersect; and
a protective layer, located on a side of the bonding pins facing away from the base material; wherein
the protective layer comprises a plurality of first openings and a plurality of second openings for exposing the plurality of bonding pins, wherein a size of the first opening is greater than a size of the second opening; one bonding pin corresponds to one first opening and at least one second opening, and the second opening is located on at least one side of the first opening in the first direction.

2. The flexible circuit board according to claim 1, wherein one bonding pin corresponds to one first opening and the plurality of second openings, and the plurality of second openings are distributed on two sides of the first opening in the first direction in an array manner.

3. The flexible circuit board according to claim 1, wherein a width of the first opening in the second direction is smaller than or equal to a width of the bonding pin in the second direction; a width of the first opening in the first direction is smaller than or equal to half a width of the bonding pin in the first direction.

4. The flexible circuit board according to claim 1, wherein the width of the bonding pin in the first direction is 0.8 mm-1.5 mm; the width of the bonding pin in the second direction is 0.1 mm-0.2 mm; a distance between two adjacent bonding pins in the second direction is 0.05 mm-0.1 mm;
a width of the first opening in the first direction is 0.3 mm-0.75 mm; the width of the first opening in the second direction is 0.06 mm-0.2 mm; and
a width of the second opening in the first direction is 0.03 mm-0.05 mm; a width of the second opening in the second direction is 0.03 mm-0.05 mm; a distance between two adjacent second openings is 0.01 mm-0.03 mm.

5. The flexible circuit board according to claim 1, further comprising:
a conductive layer, located on the bonding pin within the first opening and the second opening; wherein
a surface of a side of the conductive layer facing away from the bonding pins is flush with a surface of a side of the protective layer facing away from the bonding pins.

6. The flexible circuit board according to claim 5, wherein a material of the conductive layer comprises nickel and/or gold.

7. The flexible circuit board according to claim 1, wherein the plurality of bonding pins comprise a plurality of first bonding pins and a plurality of second bonding pins; wherein
the first bonding pin and the second bonding pin are located at two ends of the flexible circuit board respectively, and the first bonding pin and the second bonding pin are located at the same side of the base material.

8. The flexible circuit board according to claim 1, wherein the plurality of bonding pins comprise a plurality of first bonding pins and a plurality of second bonding pins; the protective layer comprises a first protective layer and a second protective layer;
the first bonding pin and the second bonding pin are located at two ends of the flexible circuit board respectively; the first bonding pin is located at one side of the base material, and the second bonding pin is located at a side of the base material facing away from the first bonding pin; the first protective layer is located on a side of the first bonding pin facing away from the base material, and the second protective layer is located on a side of the second bonding pin facing away from the base material.

9. A display device, comprising a display panel, and the flexible circuit board according to claim 1; wherein,
the display panel comprises a display area and a non-display area surrounding the display area; connecting pins are provided in the non-display area at one side of the display area;
one of the bonding pins on the flexible circuit board corresponds to one of the connecting pins on the display panel;
the bonding pins and the connecting pins corresponding to each other are bound by an anisotropic conductive adhesive film.

10. The display device according to claim 9, wherein the display panel comprises:
a base substrate;
a driving circuit layer, located on the base substrate and comprising a plurality of display signal leads;
an organic light-emitting diode device layer, located at a side of the driving circuit layer facing away from the base substrate;
a packaging layer, located at a side of the organic light-emitting diode device layer facing away from the base substrate; and
a touch functional layer, located at a side of the packaging layer facing away from the organic light-emitting diode device layer and comprising a plurality of touch signal leads; wherein
the connecting pins comprise display connecting pins and touch connecting pins; one of the display signal leads is correspondingly connected with one of the display connecting pins, and one of the touch signal leads is correspondingly connected with one of the touch connecting pins;
the display device comprises two flexible circuit boards, which are a display flexible circuit board and a touch flexible circuit board, respectively, wherein the touch flexible circuit board is configured to be bound to the touch connecting pins, and the display flexible circuit board is configured to be bound to the display connecting pins.

11. The display device according to claim 10, wherein the plurality of bonding pins in the touch flexible circuit board comprise a plurality of first touch bonding pins and a plurality of second touch bonding pins; the first touch bonding pin and the second touch bonding pin are located at two ends of the touch flexible circuit board, and the first touch bonding pin and the second touch bonding pin are located at the same side of the base material in the touch flexible circuit board;
the first touch bonding pin and the touch connecting pin are mutually bound;
the plurality of bonding pins in the display flexible circuit board comprise a plurality of first display bonding pins and a plurality of second display bonding pins, wherein the first display bonding pin and the second display bonding pin are located at two ends of the display flexible circuit board, and the first display bonding pin and the second display bonding pin are located at two sides of the base material in the display flexible circuit board;
the second display bonding pin and the display connecting pin are mutually bound;
the second touch bonding pin and the second display bonding pin are mutually bound.

12. The flexible circuit board according to claim 2, wherein a width of the first opening in the second direction is smaller than or equal to a width of the bonding pin in the second direction; a width of the first opening in the first direction is smaller than or equal to half a width of the bonding pin in the first direction.

13. The flexible circuit board according to claim 2, wherein the width of the bonding pin in the first direction is 0.8 mm-1.5 mm; the width of the bonding pin in the second direction is 0.1 mm-0.2 mm; a distance between two adjacent bonding pins in the second direction is 0.05 mm-0.1 mm;
a width of the first opening in the first direction is 0.3 mm-0.75 mm; the width of the first opening in the second direction is 0.06 mm-0.2 mm; and
a width of the second opening in the first direction is 0.03 mm-0.05 mm; a width of the second opening in the second direction is 0.03 mm-0.05 mm; a distance between two adjacent second openings is 0.01 mm-0.03 mm.

14. The flexible circuit board according to claim 3, wherein the width of the bonding pin in the first direction is 0.8 mm-1.5 mm; the width of the bonding pin in the second direction is 0.1 mm-0.2 mm; a distance between two adjacent bonding pins in the second direction is 0.05 mm-0.1 mm;
a width of the first opening in the first direction is 0.3 mm-0.75 mm; the width of the first opening in the second direction is 0.06 mm-0.2 mm; and
a width of the second opening in the first direction is 0.03 mm-0.05 mm; a width of the second opening in the second direction is 0.03 mm-0.05 mm; a distance between two adjacent second openings is 0.01 mm-0.03 mm.

15. The flexible circuit board according to claim 2, further comprising:
a conductive layer, located on the bonding pin within the first opening and the second opening; wherein
a surface of a side of the conductive layer facing away from the bonding pins is flush with a surface of a side of the protective layer facing away from the bonding pins.

16. The flexible circuit board according to claim 3, further comprising:
a conductive layer, located on the bonding pin within the first opening and the second opening; wherein
a surface of a side of the conductive layer facing away from the bonding pins is flush with a surface of a side of the protective layer facing away from the bonding pins.

17. The flexible circuit board according to claim 4, further comprising:
a conductive layer, located on the bonding pin within the first opening and the second opening; wherein
a surface of a side of the conductive layer facing away from the bonding pins is flush with a surface of a side of the protective layer facing away from the bonding pins.

18. The flexible circuit board according to claim 2, wherein the plurality of bonding pins comprise a plurality of first bonding pins and a plurality of second bonding pins; the protective layer comprises a first protective layer and a second protective layer;
the first bonding pin and the second bonding pin are located at two ends of the flexible circuit board respectively; the first bonding pin is located at one side of the base material, and the second bonding pin is located at a side of the base material facing away from the first bonding pin; the first protective layer is located on a side of the first bonding pin facing away from the base material, and the second protective layer is located on a side of the second bonding pin facing away from the base material.

19. The flexible circuit board according to claim 3, wherein the plurality of bonding pins comprise a plurality of first bonding pins and a plurality of second bonding pins; the protective layer comprises a first protective layer and a second protective layer;
the first bonding pin and the second bonding pin are located at two ends of the flexible circuit board respectively; the first bonding pin is located at one side of the base material, and the second bonding pin is located at a side of the base material facing away from the first bonding pin; the first protective layer is located on a side of the first bonding pin facing away from the base material, and the second protective layer is located on a side of the second bonding pin facing away from the base material.

20. The flexible circuit board according to claim 3, wherein the plurality of bonding pins comprise a plurality of first bonding pins and a plurality of second bonding pins; the protective layer comprises a first protective layer and a second protective layer;
the first bonding pin and the second bonding pin are located at two ends of the flexible circuit board respectively; the first bonding pin is located at one side of the base material, and the second bonding pin is located at a side of the base material facing away from the first bonding pin; the first protective layer is located on a side of the first bonding pin facing away from the base material, and the second protective layer is located on a side of the second bonding pin facing away from the base material.
